(19) United States
(12) Patent Application Publication
(10) Pub. No.: US 2023/0388716 A1
(43) Pub. Date: Nov. 30, 2023

(54) ACOUSTIC DEVICE

(71) Applicant: TDK CORPORATION, Tokyo (JP)

(72) Inventors: Takashi KATO, Tokyo (JP); Akihiro TAKEDA, Tokyo (JP)

(73) Assignee: TDK CORPORATION, Tokyo (JP)

(21) Appl. No.: 18/322,116

(22) Filed: May 23, 2023

(30) Foreign Application Priority Data
May 31, 2022 (JP) 2022-088410

(51) Int. Cl. H04R 9/04; H04R 17/00; H04R 1/34

(52) U.S. Cl. CPC H04R 9/047; H04R 17/005; H04R 1/345; H02K 41/0354

(57) ABSTRACT

An acoustic device includes: a first vibrating body having a first vibration frequency; a second vibrating body having a second vibration frequency; and a base material having a disposition surface on which the second vibrating body is disposed. In a plan view of the base material, the first vibrating body and the second vibrating body are arranged in an in-plane direction of the disposition surface.

### CROSS-REFERENCE TO RELATED APPLICATIONS

This application is based upon and claims the benefit of priority from Japanese Patent Application No. 2022-088410, filed on May 31, 2022. The entire contents of which are incorporated herein by reference.

### TECHNICAL FIELD

The present disclosure relates to an acoustic device.

### BACKGROUND

Republication Patent WO 2016/088459 describes a so-called voice coil-type speaker device. The speaker device of the related art includes a coil bobbin having an annular shape and disposed between a yoke and a magnet; a coil wound around the coil bobbin and fluctuating together with the coil bobbin; a piezoelectric element coupled to one end portion in a fluctuation direction of the coil bobbin, and fluctuating in the same direction as the fluctuation direction of the coil bobbin; and a vibrating plate coupled to the piezoelectric element. A coupling portion of the vibrating plate to the piezoelectric element and a coupling portion of the piezoelectric element to the coil bobbin are located on one straight line in the fluctuation direction of the coil bobbin.

### SUMMARY

The voice coil-type acoustic device as described above is mainly good at producing an output in a low to mid-frequency range. In the speaker device of Republication Patent WO 2016/088459, the piezoelectric element is incorporated into a voice coil-type speaker to widen an output band, but it can be considered that the degree of difficulty in adjusting output characteristics increases due to the complexity of the structure or individual variations in the characteristics of the piezoelectric element. In addition, since the size of the piezoelectric element depends on the size of the voice coil-type speaker, miniaturizing the piezoelectric element becomes essential to miniaturizing the device. In this case, it can also be considered that it becomes difficult to obtain desired output characteristics.

The present disclosure is conceived to solve the foregoing problems, and an object of the present disclosure is to provide an acoustic device capable of easily obtaining desired output characteristics with a simple configuration.

According to one aspect of the present disclosure, there is provided an acoustic device including: a first vibrating body having a first vibration frequency; a second vibrating body having a second vibration frequency; and a base material having a disposition surface on which the second vibrating body is disposed. In a plan view of the base material, the first vibrating body and the second vibrating body are arranged in an in-plane direction of the disposition surface.

In this acoustic device, by combining the first vibration frequency of the first vibrating body and the second vibration frequency of the second vibrating body, the output band is widened. In addition, in the acoustic device, the first vibrating body and the second vibrating body are arranged in the in-plane direction of the disposition surface of the base material. With such simplification of disposition, the configuration and disposition of the second vibrating body can be prevented from affecting a structure of the first vibrating body. Therefore, it becomes easy to adjust output characteristics of the piezoelectric element, and desired output characteristics can be easily obtained.

The first vibrating body and the second vibrating body may be vibrating bodies of different vibration types. In this case, by combining the vibrating bodies of different vibration types, the widening of the output band can be easily realized.

The first vibrating body may be composed of a voice coil-type vibrating body. In this case, good output characteristics in a low to mid-frequency range can be easily obtained by the voice coil-type vibrating body.

The second vibrating body may include a piezoelectric element. In this case, good output characteristics in a high-frequency range can be easily obtained by the piezoelectric element.

The second vibrating body may include a wiring member electrically connected to the piezoelectric element, and the wiring member may be led out from the second vibrating body toward the first vibrating body. In this case, it becomes easy to secure a disposition space of the wiring member when the acoustic device is attached to an external device.

The first vibrating body may include a first drive unit and a first vibrating plate, the second vibrating body may include a second drive unit and a second vibrating plate, and a first disposition direction formed by the first drive unit and the first vibrating plate in the first vibrating body and a second disposition direction formed by the second drive unit and the second vibrating plate in the second vibrating body may be oriented to face each other. In this case, since an output direction of the first vibrating body and an output direction of the second vibrating body face each other, the flow of sound generated by a combination of the first vibrating body and the second vibrating body can be suitably formed.

The second vibrating plate may be the base material. Since the base material also serves as the second vibrating plate of the second vibrating body, the configuration of the acoustic device is simplified.

The first vibrating plate may be fixed to the base material. Accordingly, the flow of sound generated by a combination of the first vibrating body and the second vibrating body can be suitably formed.

The base material may be provided with a sound hole for extracting an output of the first vibrating body and an output of the second vibrating body, and in a plan view of the base material, the second vibrating body may be located between the first vibrating body and the sound hole. In this case, the flow of sound from the first vibrating body toward the sound hole via the second vibrating body can be formed. Therefore, an output of the acoustic device can be efficiently extracted to the outside from the sound hole.

The acoustic device may further include a housing having an internal space, and the base material may constitute a wall portion of the housing such that the first vibrating body and the second vibrating body face the internal space. In this case, the flow of sound generated by a combination of the first vibrating body and the second vibrating body can be suitably formed inside the housing.

### BRIEF DESCRIPTION OF THE DRAWINGS

FIG. 1 is a perspective view showing an acoustic device according to one embodiment of the present disclosure.

FIG. 2 is a plan view showing the acoustic device shown in FIG. 1 with a cover removed.

FIG. 3 is a cross-sectional view taken along line III-III in FIG. 2.

### DETAILED DESCRIPTION

Hereinafter, a preferred embodiment of an acoustic device according to one aspect of the present disclosure will be described in detail with reference to the drawings.

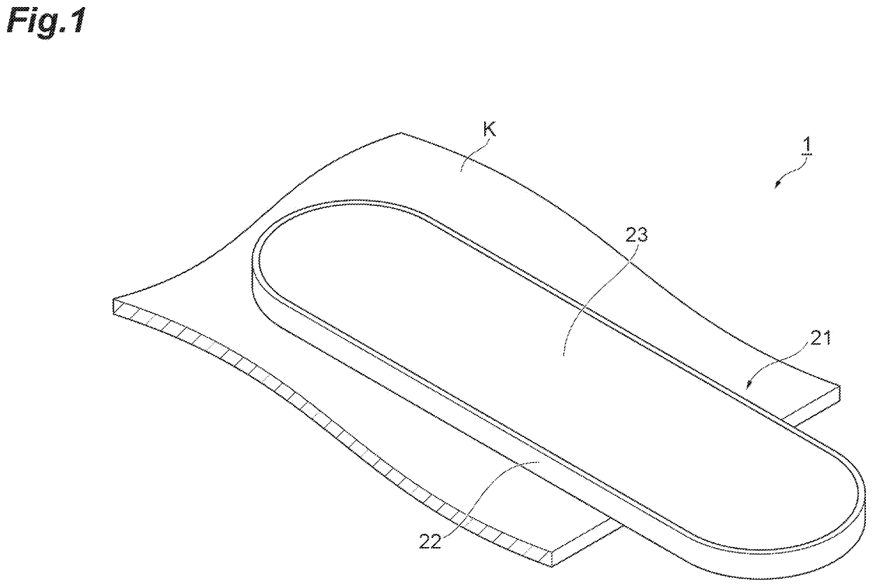

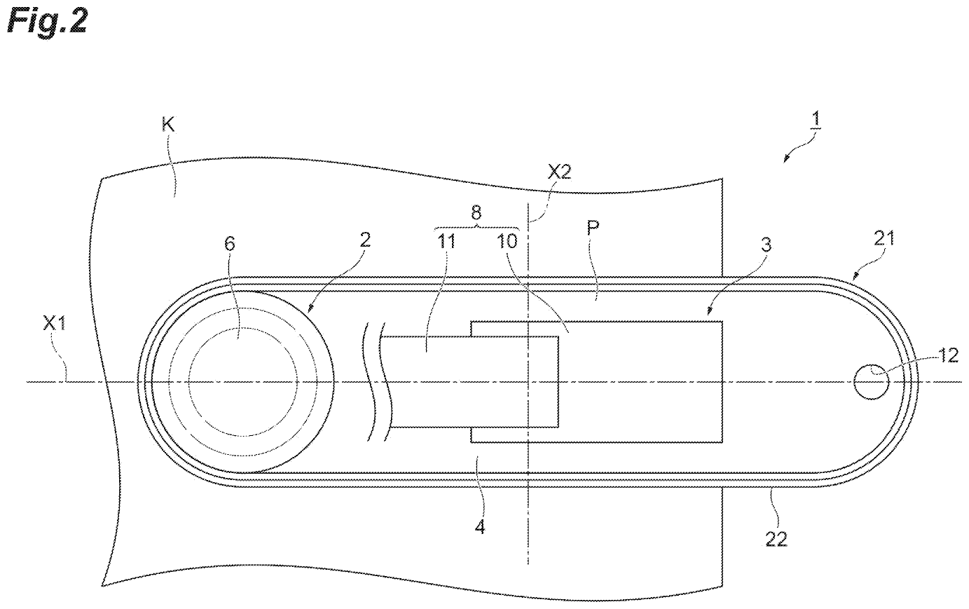

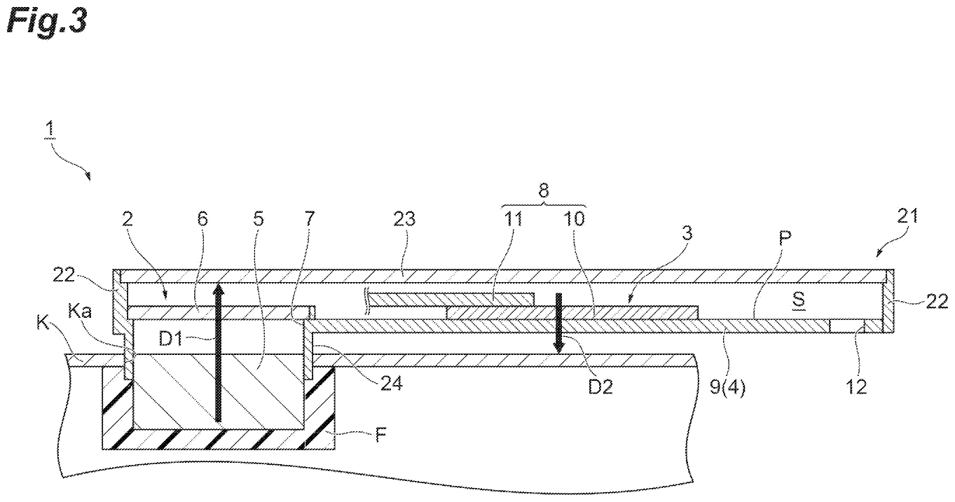

FIG. 1 is a perspective view showing an acoustic device according to one embodiment of the present disclosure. FIG. 2 is a plan view showing the acoustic device shown in FIG. 1 with a cover removed, and FIG. 3 is a cross-sectional view taken along line III-III in FIG. 2. An acoustic device 1 is, for example, a device used as an acoustic device such as a speaker or a buzzer. For example, the acoustic device 1 is attached to an external device such as a headset or a head-up display, and functions as an audio output unit of the device. Here, the acoustic device 1 is attached to a housing K constituting a main body of a head-up display.

As shown in FIGS. 1 to 3, the acoustic device 1 includes a first vibrating body 2 having a first vibration frequency; a second vibrating body 3 having a second vibration frequency; and a base material 4 on which the first vibrating body 2 and the second vibrating body 3 are disposed. In the present embodiment, the first vibrating body 2 and the second vibrating body 3 are vibrating bodies of different vibration types. The first vibrating body 2 is composed of, for example, a voice coil-type vibrating body. The second vibrating body 3 includes, for example, a piezoelectric element.

The first vibrating body 2 is a main speaker in the acoustic device 1, and is mainly responsible for output in a low to mid-frequency range. The second vibrating body 3 is a sub-speaker in the acoustic device 1, and is mainly responsible for output in a high-frequency range. The bands of the first vibration frequency and the second vibration frequency may partially overlap. In the present embodiment, the first vibration frequency of the first vibrating body 2 is, for example, approximately 20 Hz to 5 kHz. In addition, the second vibration frequency of the second vibrating body 3 is, for example, approximately 5 kHz to 20 kHz.

The first vibrating body 2 includes a first drive unit 5 and a first vibrating plate 6. The first drive unit 5 is disposed in a disposition hole Ka provided in the housing K of the external device, so as not to protrude from the disposition hole Ka (refer to FIG. 3). The first drive unit 5 is, for example, fixed to a peripheral edge portion of the disposition hole Ka by a fixing member F such as an adhesive agent.

The first drive unit 5 includes, for example, a magnet, a yoke, and a coil bobbin. The magnet has, for example, an annular shape, and a part of the yoke is inserted into a center hole of the magnet. A space is formed as a magnetic gap between the magnet and the insertion portion of the yoke. The coil bobbin is disposed in the magnetic gap. A coil is wound around an outer periphery of the coil bobbin. Since the coil is disposed in the magnetic gap, a magnetic circuit is formed by the coil, the magnet, and the yoke.

The first vibrating plate 6 is disposed at a certain distance from the first drive unit 5. The first vibrating plate 6 has a circular shape in a plan view (refer to FIG. 2). The first vibrating plate 6 is fixed to the base material 4. More specifically, the first vibrating plate 6 is disposed to block a disposition hole 7 in the base material 4, and a peripheral edge portion of the first vibrating plate 6 is fixed to a peripheral edge portion of the disposition hole 7 in the base material 4 by adhesion or the like. The first vibrating plate 6 vibrates when the coil bobbin is fluctuated by the driving of the magnetic circuit in the first drive unit 5, and outputs sound based on the first vibration frequency.

The second vibrating body 3 includes a second drive unit 8 and a second vibrating plate 9. The second drive unit 8 includes a piezoelectric element 10 and a wiring member 11. In the present embodiment, the piezoelectric element 10 has a rectangular parallelepiped shape that is flat in a thickness direction. The rectangular parallelepiped shape can also include a shape with chamfered corners and edges or a shape with rounded corners and edges.

The piezoelectric element 10 includes a piezoelectric body and a pair of external electrodes. The piezoelectric body is composed of a laminate of a plurality of piezoelectric body layers. Each of the piezoelectric body layers is made of a piezoelectric material such as piezoelectric ceramic. Examples of the piezoelectric ceramic material include PZT[Pb(Zr, Ti)O₃], PT(PbTiO₃), PLZT[(Pb, La)(Zr, Ti)₃], barium titanate (BaTiO₃), and the like.

Each of the piezoelectric body layers is composed of, for example, a sintered body of ceramic green sheets containing the above-described piezoelectric ceramic. In the actual piezoelectric body, the piezoelectric body layers are integrated to such an extent that boundaries between the piezoelectric body layers cannot be recognized. A plurality of internal electrodes (not shown) are disposed inside the piezoelectric body. Each of the internal electrodes is made of a conductive material. Examples of the conductive material include Ag, Pd, Ag—Pd alloy, and the like.

The second drive unit 8 is, for example, directly joined to the base material 4 by a joining member such as double-sided tape. Therefore, in the present embodiment, the second vibrating plate 9 is composed of the base material 4 itself. The base material 4 as the second vibrating plate 9 vibrates when the piezoelectric element 10 in the second drive unit 8 fluctuates in the thickness direction, and outputs sound based on the second vibration frequency.

The wiring member 11 is a member electrically connecting the piezoelectric element 10 and the external device. The wiring member 11 is, for example, a flexible printed circuit (FPC) board. One end side of the wiring member 11 is electrically connected to each of the pair of external electrodes of the piezoelectric element 10. For example, an anisotropic conductive adhesive material can be used for connection between the one end side of the wiring member 11 and the external electrodes of the piezoelectric element 10.

As shown in FIG. 2, the other end side of the wiring member 11 is led out from the second vibrating body 3 toward the first vibrating body 2. The other end side of the wiring member 11 is, although not shown, led out from the disposition hole 7 of the base material 4 or an insertion hole provided separately from the disposition hole 7, to a housing K side, and is electrically connected to a control device or the like on an external device side inside the housing K. Incidentally, the wiring member 11 may not necessarily be led out from the second vibrating body 3 toward the first vibrating body 2 or may be led out from the second vibrating body 3 to a side opposite to the first vibrating body 2. The wiring member 11 may be led out from the second vibrating body 3 in a minor-axis direction of the base material 4.

The base material 4 is, for example, formed in a plate shape from plastic or metal. When the base material 4 is made of metal, there is a tendency that the speed of sound increases and high-frequency sounds are easily produced. In addition, since the rigidity is relatively high, the sound pressure tends to be high at a specific frequency. When the base material 4 is made of plastic, the output frequency range tends to be lower compared to the case of metal. In addition, since the rigidity is relatively low, there is a tendency that internal loss occurs and a change in sound pressure due to frequency becomes smooth.

One surface side of the base material 4 is a disposition surface P on which the second vibrating body 3 is disposed. The other surface side of the base material 4 is a surface facing the housing K side of the external device. In the present embodiment, as shown in FIG. 2, the planar shape of the base material 4 is an oval shape with one direction as a major axis X1 and a direction orthogonal thereto as a minor axis X2. The disposition hole 7 (refer to FIG. 3) with a circular cross-section in which the first vibrating body 2 described above is disposed is provided on one end side in a major-axis direction of the base material 4.

A sound hole 12 for extracting an output of the first vibrating body 2 and an output of the second vibrating body 3 is provided on the other end side in the major-axis direction of the base material 4. In the example of FIG. 2, the cross-sectional shape of the sound hole 12 is, for example, a circular shape with a smaller diameter than that of the disposition hole 7. The cross-sectional shape of the sound hole 12 is not limited thereto, and may be other shapes such as an elliptical shape, an oval shape, a triangular shape, a rectangular shape, and a polygonal shape. The sound hole 12 is not limited to a single sound hole, and a plurality of the sound holes 12 may be provided in a certain region. When the plurality of sound holes 12 are provided, a combination of the sound holes 12 with different areas may be used.

In a plan view of the base material 4, as shown in FIG. 2, the first vibrating body 2 and the second vibrating body 3 are arranged in an in-plane direction of the disposition surface P. More specifically, in the present embodiment, in a plan view of the base material 4, the first vibrating body 2, the second vibrating body 3, and the sound hole 12 are arranged on the major axis X1 in order from the one end side to the other end side in the major-axis direction of the base material 4. The second vibrating body 3 (piezoelectric element 10) is located between the first vibrating body 2 and the sound hole 12 in a state where the second vibrating body 3 is separated from each of the first vibrating body 2 and the sound hole 12. Since the wiring member 11 is led out to a first vibrating body 2 side, the piezoelectric element 10 is located toward the sound hole 12 on the major axis X1 of the base material 4.

In the present embodiment, as shown in FIGS. 1 to 3, the acoustic device 1 includes a housing 21 having an internal space S. The housing 21 includes the base material 4, a peripheral wall portion 22, and a cover 23 (refer to FIG. 1). The base material 4 constitutes a wall portion of the housing 21 such that the first vibrating body 2 and the second vibrating body 3 face the internal space S (exposed to an internal space S side). The peripheral wall portion 22 is erected along a peripheral edge portion of the base material 4. The planar shape of the cover 23 is the same oval shape as the planar shape of the base material 4. The cover 23 is fitted to the peripheral wall portion 22 to face the base material 4 at a predetermined distance, and forms the internal space S between the cover 23 and the base material 4.

The internal space S is in a sealed state except for the sound hole 12, and forms a vibration space in the acoustic device 1. The flow of sound from the first vibrating body 2 and the second vibrating body 3 toward the sound hole 12 is formed in the internal space S. In order to form the flow of sound, in the acoustic device 1, as shown in FIG. 3, a first disposition direction D1 formed by the first drive unit 5 and the first vibrating plate 6 in the first vibrating body 2 and a second disposition direction D2 formed by the second drive unit 8 and the second vibrating plate 9 in the second vibrating body 3 are oriented to face each other.

In the present embodiment, the first disposition direction D1 and the second disposition direction D2 are oriented to face each other. In the first vibrating body 2, the first drive unit 5 is disposed in the disposition hole Ka of the housing K of the external device, and the first vibrating plate 6 is disposed in the disposition hole 7 of the base material 4. Therefore, the first disposition direction D1 formed by the first drive unit and the first vibrating plate 6 in the first vibrating body 2 is oriented from the base material 4 toward the cover 23 (oriented from the other surface side toward the one surface side (disposition surface P side) of the base material 4). In the second vibrating body 3, the second drive unit 8 is disposed to face the internal space S on the disposition surface P of the base material 4, and the second vibrating plate 9 is the base material 4. Therefore, the second disposition direction D2 formed by the second drive unit 8 and the second vibrating plate 9 in the second vibrating body 3 is oriented from the cover 23 toward the base material 4 (oriented from the one surface side (disposition surface P side) toward the other surface side of the base material 4).

A sound output by the first vibrating body 2 mainly passes through the internal space S from the first vibrating plate 6, and is output to the outside from the sound hole 12. In addition, in the present embodiment, since the first vibrating plate 6 is fixed to the base material 4, a part of the sound output by the first vibrating body 2 is output to the outside from the sound hole 12 via the base material 4. In the present embodiment, since the second vibrating plate 9 is the base material 4, a sound output by the second vibrating body 3 is mainly output to the outside from the sound hole 12 via the base material 4. A part of the sound output by the second vibrating body 3 passes through the internal space S from the second vibrating plate 9, and is output to the outside from the sound hole 12.

In the present embodiment, the housing 21 includes a protruding portion 24 used for joining to the housing K of the external device. The protruding portion 24 is formed in an annular shape to correspond the peripheral edge portion of the disposition hole 7 of the base material 4, and protrudes opposite to the disposition surface P. A tip portion of the protruding portion 24 is fitted into the disposition hole Ka of the housing K of the external device, and is fixed to the housing K by the fixing member F described above, together with the first drive unit 5 of the first vibrating body 2. With such a configuration, the housing K of the external device is separated from the base material 4 by a distance corresponding to the amount of protrusion of the protruding portion 24 from the base material 4. Similarly, the first drive unit 5 is separated from the base material 4 by a distance corresponding to the amount of protrusion of the protruding portion 24 from the base material 4.

As described above, in the acoustic device 1, by combining the first vibration frequency of the first vibrating body 2 and the second vibration frequency of the second vibrating body 3, the output band is widened. In addition, in the acoustic device 1, the first vibrating body 2 and the second vibrating body 3 are arranged in the in-plane direction of the disposition surface P of the base material 4. With such simplification of disposition, the configuration and disposition of the second vibrating body 3 can be prevented from affecting a structure of the first vibrating body 2. Therefore, it becomes easy to adjust output characteristics of the piezoelectric element 10, and desired output characteristics can be easily obtained.

In the present embodiment, the first vibrating body 2 and the second vibrating body 3 are vibrating bodies of different vibration types. In such a manner, by combining the vibrating bodies of different vibration types, the widening of the output band can be easily realized. The first vibrating body 2 is composed of a voice coil-type vibrating body. Accordingly, good output characteristics in a low to mid-frequency range can be easily obtained by the voice coil-type vibrating body. The second vibrating body 3 includes the piezoelectric element 10. Accordingly, good output characteristics in a high-frequency range can be easily obtained by the piezoelectric element 10.

In the present embodiment, the second vibrating body 3 includes the wiring member 11 electrically connected to the piezoelectric element and the wiring member 11 is led out from the second vibrating body 3 toward the first vibrating body 2. Accordingly, it becomes easy to secure a disposition space of the wiring member 11 when the acoustic device 1 is attached to the external device.

In the present embodiment, the first vibrating body 2 includes the first drive unit 5 and the first vibrating plate 6, and the second vibrating body 3 includes the second drive unit 8 and the second vibrating plate 9. Further, the first disposition direction D1 formed by the first drive unit 5 and the first vibrating plate 6 in the first vibrating body 2 and the second disposition direction D2 formed by the second drive unit 8 and the second vibrating plate 9 in the second vibrating body 3 are oriented to face each other. According to such a configuration, since an output direction of the first vibrating body 2 and an output direction of the second vibrating body 3 face each other, the flow of sound generated by a combination of the first vibrating body 2 and the second vibrating body 3 can be suitably formed.

In the present embodiment, the second vibrating plate 9 is the base material 4. Since the base material 4 also serves as the second vibrating plate 9 of the second vibrating body 3, the configuration of the acoustic device 1 is simplified. In addition, in the present embodiment, the first vibrating plate 6 is fixed to the base material 4. Accordingly, the flow of sound generated by a combination of the first vibrating body 2 and the second vibrating body 3 can be suitably formed.

In the present embodiment, the base material 4 is provided with the sound hole 12 for extracting an output of the first vibrating body 2 and an output of the second vibrating body 3. In a plan view of the base material 4, the second vibrating body 3 is located between the first vibrating body 2 and the sound hole 12. Accordingly, the flow of sound from the first vibrating body 2 toward the sound hole via the second vibrating body 3 can be formed. Therefore, an output of the acoustic device 1 can be efficiently extracted to the outside from the sound hole 12.

In the present embodiment, the acoustic device 1 includes the housing 21 having the internal space S. The base material 4 constitutes the wall portion of the housing 21 such that the first vibrating body 2 and the second vibrating body 3 face the internal space S. With such a configuration, the flow of sound generated by a combination of the first vibrating body 2 and the second vibrating body 3 can be suitably formed inside the housing 21.

What is claimed is:

1. An acoustic device comprising:
a first vibrating body having a first vibration frequency;
a second vibrating body having a second vibration frequency; and
a base material having a disposition surface on which the second vibrating body is disposed,
wherein in a plan view of the base material, the first vibrating body and the second vibrating body are arranged in an in-plane direction of the disposition surface.

2. The acoustic device according to claim 1,
wherein the first vibrating body and the second vibrating body are vibrating bodies of different vibration types.

3. The acoustic device according to claim 2,
wherein the first vibrating body is composed of a voice coil-type vibrating body.

4. The acoustic device according to claim 2,
wherein the second vibrating body includes a piezoelectric element.

5. The acoustic device according to claim 4,
wherein the second vibrating body includes a wiring member electrically connected to the piezoelectric element, and
the wiring member is led out from the second vibrating body toward the first vibrating body.

6. The acoustic device according to claim 1,
wherein the first vibrating body includes a first drive unit and a first vibrating plate,
the second vibrating body includes a second drive unit and a second vibrating plate, and
a first disposition direction formed by the first drive unit and the first vibrating plate in the first vibrating body and a second disposition direction formed by the second drive unit and the second vibrating plate in the second vibrating body are oriented to face each other.

7. The acoustic device according to claim 6,
wherein the second vibrating plate is the base material.

8. The acoustic device according to claim 7,
wherein the first vibrating plate is fixed to the base material.

9. The acoustic device according to claim 1,
wherein the base material is provided with a sound hole for extracting an output of the first vibrating body and an output of the second vibrating body, and
in a plan view of the base material, the second vibrating body is located between the first vibrating body and the sound hole.

10. The acoustic device according to claim 1, further comprising:
a housing having an internal space,
wherein the base material constitutes a wall portion of the housing such that the first vibrating body and the second vibrating body face the internal space.
